(19) United States
(12) Patent Application Publication
(10) Pub. No.: US 2003/0064154 A1
(43) Pub. Date: Apr. 3, 2003

(54) Low-K dielectric thin films and chemical vapor deposition method of making same

(76) Inventors: Ravi K. Laxman, San Jose, CA (US); Chongying Xu, Milford, CT (US); Thomas H. Baum, New Fairfield, CT (US)

Correspondence Address: Margaret Chappuis, ATMI, Inc., 7 Commerce Drive, Danbury, CT, 06810, US

(21) Appl. No.: 10/213,395

(22) Filed: Aug. 6, 2002

Related U.S. Application Data
(60) Provisional application No. 60/310,309, filed on Aug. 6, 2001.

(51) Int. Cl. C23C 16/00

(52) U.S. Cl. 427/255.28; 427/569

(57) ABSTRACT

A CVD process for producing low-dielectric constant, SiOC thin films using organosilicon precursor compositions having at least one alkyl group and at least one cleavable organic functional group that when activated rearranges and cleaves as a highly volatile liquid or gaseous by-product. In a first step, a dense SiOC thin film is CVD deposited from the organosilicon precursor having at least one alkyl group and at least one cleavable organic functional group, having retained therein at least a portion of the alkyl and cleavable organic functional groups. In a second step, the dense SiOC thin film is post annealed to effectively remove the volatile liquid or gaseous by-products, resulting in a porous low-dielectric constant SiOC thin film. The porous, low dielectric constant, SiOC thin films are useful as insulating layers in microelectronic device structures. Preferred porous, low-dielectric SiOC thin films are produced using di(formato)dimethylsilane as the organosilicon precursor.

### TECHNICAL FIELD OF THE INVENTION

The present invention relates to a process for forming low-k dielectric thin films useful as insulating materials in microelectronic device structures. More particularly, the present invention is directed to a CVD process for forming porous, low-dielectric constant, SiOC thin films having dielectric constants of less than 2.7.

### BACKGROUND OF THE INVENTION

As the need for integrated circuits for semiconductor devices having higher performance and greater functionality increases, device feature geometries continue to decrease. As device geometries become smaller, the dielectric constant of an insulating material used between conducting paths becomes an increasingly important factor in device performance.

As device dimensions shrink to less than 0.25 μm, propagation delay, cross-talk noise and power dissipation due to resistance-capacitance (RC) coupling become significant due to increased wiring capacitance, especially interline capacitance between the metal lines on the same level. These factors all depend critically on the dielectric constant of the separating insulator.

The use of low-k dielectric(K) materials advantageously lowers power consumption, reduces cross talk, and shortens signal delay for closely spaced conductors through reduction of both nodal and interconnect line capacitances. Dielectric materials, which exhibit low dielectric constants, are critical in the development path toward faster and more power efficient microelectronics.

Silicon oxide (SiO₂), with a dielectric constant of approximately 4, has long been used in integrated circuits as the primary insulating material. However, the interconnect delay associated with SiO₂ is a limiting factor in advanced integrated circuits.

In order to produce faster and more power efficient microelectronics with smaller device geometries, insulating materials having dielectric constants of less than 3.0 are necessary. One approach to lowering the dielectric constant of the SiO₂ insulating layer is by incorporation of carbon. Carbon incorporation from between 15-20%, reduces the dielectric constant to as low as 2.7, in part due to the substitution of the highly polarized Si—O link by Si—C, (i.e., Nakano, et al., “Effects of Si—C Bond Content on Film Properties of Organic Spin-on Glass” J. Electrochem. Soc., Vol. 142, No. 4, Apr. 1995, pp. 1303-1307).

Alkyl silanes, alkoxy silanes and cyclic-siloxanes such as 2,4,6,8-tetramethylcyclotetrasiloxane (TMCTS) are being evaluated aggressively for obtaining low-k dielectric(k) thin-films as interlayer dielectrics in an integrated circuit by a PECVD approach. The resulting films formed when using these precursors give dense SiOC containing films, having dielectric constants in the range of from about 2.7 to 3.0.

A second approach to lowering the dielectric constant is to use porous, low-density, silicon oxide materials in which a fraction of the bulk volume of the SiO₂ film contains air, which has a dielectric constant of 1.

As an example, silica aerogels are porous solids having dielectric constants in the range of from about 2.0 to 1.01 (i.e., Lu, et al., “Low-k dielectric Materials—Synthesis and Applications in Microelectronics”, Mat. Res. Soc. Sym. Proc., Apr. 17-19, San Francisco, Calif., 1995, pp. 267-272). The silica aerogels are prepared by sol-gel techniques, which are not well adapted for high-throughput semiconductor processing environments, due to long processing times, saturated alcohol atmospheres, and, in many applications, high pressures for supercritical solvent extraction.

Chemical vapor deposition (CVD) is the thin film deposition method of choice for large-scale fabrication of microelectronic device structures, and the semiconductor manufacturing industry has extensive expertise in its use.

It would therefore be a significant advance in the art to provide a high throughput CVD process, for producing low dielectric constant, silica thin films on a substrate, having dielectric constants less than 3.0.

It therefore is an object of the present invention to provide such process for producing low-k dielectric silica thin films on a substrate, having dielectric constants less than 3.0.

Other objects and advantages of the present invention will be more fully apparent from the ensuing disclosure and appended claims.

### SUMMARY OF THE INVENTION

The present invention is directed to the formation of a porous, low-k dielectric SiOC thin film by a process, which comprises chemical vapor depositing on a substrate, a low-k dielectric thin film from an organosilicon composition containing at least one cleavable organic functional group that upon activation rearranges and cleaves as a highly volatile liquid and/or gaseous species, to produce a porous, SiOC, thin film having a dielectric constant of less than 3.0.

As used herein, the term “low-k dielectric” refers to a dielectric material having a value of the dielectric constant, k, below 3.0 as measured at a frequency of 1 mega-Hertz. The term “thin film” refers to a film having a thickness in the range of from about 1000 Å to about 2 μm and the term “SiOC” refers to a thin film composition comprising from about 1 to about 40 atomic percent silicon, preferably from about 20 to 40 percent silicon, from about 1 to about 60 atomic percent oxygen, preferably from about 40 to 60 percent oxygen and from about 1 to about 20 atomic percent carbon and preferably from 5 to 17 percent carbon.

In one aspect, the present invention relates to an organosilicon low-k dielectric precursor useful for producing porous, low-k dielectric, SiOC thin films wherein the organosilicon precursor comprises at least one cleavable, organic functional group that upon activation rearranges, decomposes and/or cleaves as a highly volatile liquid and/or gaseous by-product.

As used herein, the term cleavable refers to an organic functional group, bonded to the silicon atom of the organosilicon precursor that when activated (i.e., thermal, light or plasma enhanced), rearranges, decomposes and/or is liberated as a volatile liquid or gaseous by-product, i.e. CO₂.

In a preferred aspect of the invention the organosilicon precursor is di(formato)dimethylsilane, a novel composition useful for the deposition of low-k dielectric thin films, comprising the formula:

(CH₃)₂Si(OOCH)₂

In a further aspect, the present invention relates to a method of synthesizing di(formato)dimethylsilane by a method comprising:

2M¹(OOCH)+(CH₃)₂SiCl₂→(CH₃)₂Si(OOCH)₂+2M¹Cl

wherein M¹ is selected from the group consisting of Na (sodium), K (potassium) and Ag (silver).

In a further aspect the present invention relates to a CVD process for producing, porous, low dielectric constant, SiOC thin films on a substrate, from at least one low-k dielectric, organosilicon precursor comprising at least one cleavable, organic functional group that upon activation, rearranges, decomposes and/or cleaves as a highly volatile liquid or gaseous by-product.

In yet another aspect, the present invention relates to a porous, low-k, dielectric, SiOC thin film produced by the CVD process as described hereinabove.

In a still further aspect, the present invention relates to a porous, low-k, dielectric, SiOC thin film having a hardness of greater than 1.0 Gpa,, produced by the CVD process as described hereinabove.

### BRIEF DESCRIPTION OF THE DRAWINGS

FIG. 1 shows a simplified schematic representation of a process system for forming a low dielectric constant thin film on a substrate in accordance with one embodiment of the invention.

FIG. 2 shows a simplified schematic representation of a process system for forming a low dielectric constant thin film on a substrate in accordance with a further embodiment of the invention.

FIG. 3 shows a mass spectroscopic analysis of di(formato)dimethylsilane.

### DETAILED DESCRIPTION OF THE INVENTION AND PREFERRED EMBODIMENTS THEREOF

The present invention contemplates the use of organosilicon precursors for CVD formation of porous low-k dielectric thin films, in which the precursor composition contains at least one cleavable organic functional group that upon activation, rearranges, decomposes and/or cleaves as a highly volatile liquid or gaseous by product.

In one embodiment (hereinafter referred to as Embodiment 1) the invention relates to organosilicon precursors for producing porous, low-k dielectric, SiOC thin films, wherein the composition of the organosilicon precursor comprises at least one cleavable organic functional group that upon activation, rearranges, decomposes and/or cleaves as a highly volatile liquid or gaseous by product.

In a further embodiment (hereinafter referred to as Embodiment 2) the invention relates to organosilicon precursors useful for producing porous, low-k dielectric, SiOC thin films, comprising the general formula:

I.

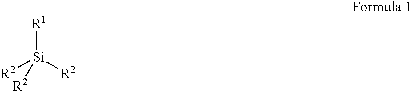

wherein

R¹ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinbelow, and ligand Y as described hereinbelow; and

each of R² is same or different and each of R² is selected from the group consisting of H, ligand X as described hereinbelow, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀aryl, C₆ to C₁₀ fluoroaryl, C₆ to C₁₀ perfluoroaryl and C₂ to C₆ alkylsilane;

II.

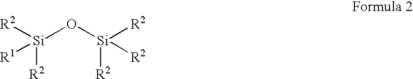

wherein

R¹ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinbelow, and ligand Y as described hereinbelow; and

each of R² is same or different and each of R² is selected from the group consisting of H, ligand X as described hereinbelow, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane; and

III.

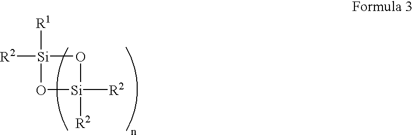

wherein

R¹ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinbelow, and ligand Y as described hereinbelow; and

each of R² is same or different and each of R² is selected from the group consisting of H, ligand X as described hereinbelow, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane, and

n is an integer from 1 to 6.

In the Formula 3 composition as outlined hereinabove, at least one of R² may further comprise at least one cross-linking functional group, which upon activation forms intermolecular bridging —Si—O—Si— bonds. Useful Si—O—Si cross-linking functional groups include but are not limited to Si—H, Si—OH, alcohols, phenols, alkoxysilanes, epoxides, esters, methacrylates, styrenes, silanols, silanes, olefins, norborenes. Preferred cross-linking functional groups include Si—H and Si—OH.

In a further embodiment (hereinafter referred to as Embodiment 3) the invention relates to organosilicon precursors useful for producing porous, low dielectric constant, SiOC thin films, wherein the organosilicon precursor comprises a composition containing at least one alkyl group and at least one organic functional group that upon activation, rearranges, decomposes and/or cleaves as a highly volatile liquid or gaseous by product.

In a further embodiment (hereinafter referred to as Embodiment 4) the invention relates to organosilicon precursors for producing porous, low dielectric constant, SiOC thin films, comprising the general formula:

IV.

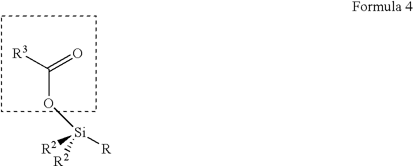

wherein

ligand X is a cleavable organic functional group as depicted in Formula 4;

R³ is selected from the group consisting of: H, C₁ to C₆ alkyl, C₁ to C₆ fluoroalkyl, C₁ to C₆ perfluoroalkyl, C₃ to C₆ cycloalkyl, C₃ to C₄ allyl, C₂ to C₆ alkene, C₆ to C₁₀ aryl, C₆ to C₁₀ fluoroaryl, C₆ to C₁₀ perfluoroaryl, C₁ to C₆ carboxylate;

R is selected from the group consisting of; C₁ to C₄ alkyl, C₁ to C₄ fluoroalkyl and C₁ to C₄ perfluoroalky,

each of R² is same or different and each of R² is selected from the group consisting of H, ligand X as described hereinbelow, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁ aryl, C₆ to C₁₀ fluoroaryl, C₆ to C₁₀ perfluoroaryl and C₂ to C₆ alkylsilane;

V.

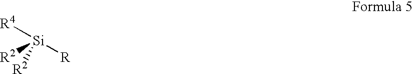

wherein

R⁴ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinabove, and ligand Y as described hereinbelow,

R is selected from the group consisting of: C₁ to C₄ alkyl, C₁ to C₄ fluoroalkyl and C₁ to C₄ perfluoroalkyl, and

each of R² is same or different and each of R² is selected from the group consisting of H, ligand X as described hereinabove, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane;

VI.

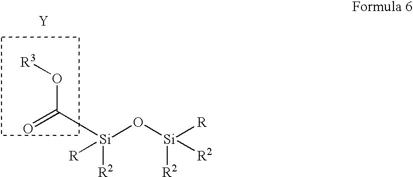

wherein

ligand Y is a cleavable organic functional group as depicted in Formula 6;

R³ is selected from the group consisting of: H, C₁ to C₆ alkyl, C₁ to C₆ fluoroalkyl, C₁ to C₆ perfluoroalkyl, C₃ to C₆ cycloalkyl, C₃ to C₄ allyl, C₂ to C₆ alkene, C₆ to C₁₀ aryl, C₆ to C₁₀ fluoroaryl, C₆ to C₁₀ perfluoroaryl, C₁ to C₆ carboxylate,

R is selected from the group consisting of: C₁ to C₄ alkyl, C₁ to C₄ fluoroalkyl and C₁ to C₄ perfluoroalkyl, and

each of R² is same or different and each of R² is selected from the group consisting of H, ligand X as described hereinabove, ligand Y as described hereinabove, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁ perfluoroaryl and C₂ to C₆ alkylsilane;

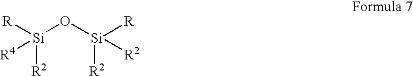

wherein

R⁴ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀fluoroaryl ligand X as described hereinabove, and ligand Y as described hereinabove,

R is selected from the group consisting of: C₁ to C₄ alkyl, C₁ to C₄ fluoroalkyl and C₁ to C₄ perfluoroalkyl, and

each of R² is same or different and each of R² is selected from the group consisting of H, ligand X as described hereinabove, ligand Y as described hereinabove, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀aryl, C₆ to C₁₀fluoroaryl, C₆ to C₁₀perfluoroaryl and C₂ to C₆ alkylsilane;

VIII.

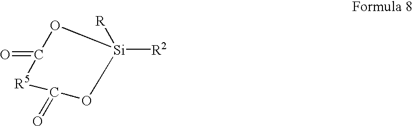

wherein

R⁵ is optional and may be selected from the group consisting of C₁ to C₂ alkyl,

R is selected from the group consisting of: C₁ to C₄ alkyl, C₁ to C₄ fluoroalkyl and C₁ to C₄ perfluoroalkyl, and

each of R² is same or different and each of R² is selected from the group consisting of H, ligand X as described hereinabove, ligand Y as described hereinabove, C₂ to C₆ alkene, C₂ to C₆ alkyne, C₃ to C₄ allyl, C₁ to C₆ alkyl, C₁ to C₆ fluoroalkyl, C₁ to C₆ perfluoroalkyl, C₃ to C₆ cycloalkyl, C₃ to C₆ fluorocycloalkyl, C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane; and

XI.

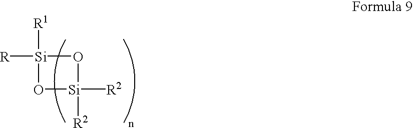

wherein

R¹ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinabove, and ligand Y as described hereinabove;

R is selected from the group consisting of: C₁ to C₄ alkyl, C₁ to C₄ fluoroalkyl and C, to C₄ perfluoroalkyl, and

each of R² is same or different and each of R² is selected from the group consisting of H, ligand X as described hereinabove, ligand Y as described hereinabove, OH, C₂ to C₆ alkene, C₂ to C₆ alkyne, C₃ to C₄ allyl, C₁ to C₆ alkyl, , C₁ to C₆, fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₁ to C₆ perfluoroalkoxy, C₆ to C₁₀ aryl, C₆ to C₁₀ fluoroaryl, C₆ to C₁₀ perfluoroaryl and C₂ to C₆ alkylsilane, C₂ to C₆ alkoxylsilane, C₂ to C₆ alkenesilane, C₂ to C₆ alkynesilane, and C₃ to C₄ allylsilane; and

n is an integer from 1 to 6.

In the Formula 9 composition as outlined hereinabove, at least one of R² may further comprise at least one cross-linking functional group, which upon activation forms intermolecular bridging —Si—O—Si— bonds. Useful Si—O—Si cross-linking functional groups include but are not limited to Si—H, Si—OH, alcohols, phenols, alkoxysilanes, epoxides, esters, methacrylates, styrenes, silanols, silanes, olefins, norborenes. Preferred cross-linking functional groups include Si—H and Si—OH.

The low-k dielectric precursors of the instant invention comprise at least one cleavable organic group that upon activation, rearranges, decomposes and/or cleaves as a highly volatile liquid or gaseous by product. As the cleavable organic group is activated , a pore or void results in the deposited thin film. Examples of the volatile by-products produced by the activation step of the present invention include but are not limited to:

| Cleavable functional group | Volatile by-product |
|---|---|
| carboxylate | CO, HCOH, CO₂ |
| dicarboxylate | CO, HOCH, CO₂ |
| alkene | alkynes, hydrocarbons |
| alkyne | hydrocarbons |
| alkyl | alkene |
| benzylate | CO₂, phenyl, benzene |

The precursors of the instant invention are selected based on the desired characteristics of the resulting low-k dielectric thin film layer. By varying the geometry and R groups as well as the process parameters, thin film properties such as porosity, carbon content, hardness, density, cross linking etc. can be controlled.

Incorporation of porosity is key to lowering the dielectric constant of conventional SiO₂ films. However, as a consequence of increasing the porosity, the elastic modulus and hardness of the low k dielectric film decrease. Incorporation of cross-linking functional groups into the low-k dielectric precursor composition and subsequent deposited thin film, increases the number of potential cross-linking sites, which advantageously imparts increased hardness and elastic modulus to the resultant film.

The precursors of the instant invention, when deposited by CVD, produce low-k dielectric thin films having the benefits of carbon incorporation and micro-porosity. The cyclosiloxane composition of Formula 9 provides a further benefit in that by adding specific reactive sites to the R groups, it is possible to control the degree of intermolecular cross-linking. Micro-porosity and carbon incorporation serve to lower the dielectric constant and Si—O—Si cross-linking serves to impart hardness to the product thin film.

The cyclic organosilicon low-k dielectric precursors of Formula 9, retain a substantial portion of the ring structure entangled and randomly oriented in the as deposited thin film, which creates voids and attributes to the reduction of the dielectric constant. By introducing cleavable functional groups and active cross-linking sites to the precursor composition it is possible to further reduce the dielectric constant, while simultaneously increasing the hardness of the thin film to a range that is between 1.0-3.0 Gpa

In a preferred embodiment, (hereinafter referred to as Embodiment 5) the present invention relates to di(formato)dimethylsilane, a novel organosilicon precursor composition useful for producing low-k dielectric thin films, comprising the formula:

(CH₃)₂Si(OOCH)₂

The organosilicon compositions of the invention are usefully employed to form low-k dielectric thin films on substrates by chemical vapor deposition. More particularly diformatodimethylsilane is useful for producing porous, low dielectric constant, SiOC thin films.

In a further embodiment the present invention relates to a method of synthesizing di(formato)dimethylsilane by a method comprising:

2M¹(OOCH)+(CH₃)₂SiCl₂→(CH₃)₂Si(OOCH)₂+2M¹Cl

wherein M¹ is selected from the group consisting of: Na(sodium), K (potassium) and Ag (silver).

Other synthetic approaches may be usefully employed for the synthesis of di(formato)dimethylsilane as well as other organosilicon compositions with equal success. In no way should the synthetic approach limit the scope of the present invention.

Specific examples of organosilicon precursors useful in the present invention, include but are not limited to: di(formato)methylsilane; di(formato)dimethylsilane; tri(formato)methylsilane; 1,3,dimethyl 1,1,3,3-tetra(formato)disiloxane; 1,3-di(formato)disiloxane; diethyldimethylsilane; triethylmethylsilane; di(t-butyl)methoxysilane, 1,3-Diethyl-1,3-dimethyldisiloxane; di-t-butylsilane; 1,3-di-t-butyl-1,1,3,3-tetramethyldisiloxane; di-isopropylsilane; 1,3-di-isopropyl-1,1,3,3-tetramethyldisiloxane; di-isobutylsilane; 1,3-di-isobuty-1-1,1,3,3,-tetramethyldisiloxane; t-butylsilane; 1,3-di-t-butyl-1,1,3,3- tetramethyldisiloxane; 1,3-diethyny-1,1,3,3-tetramethyldisiloxane; 1,3-diethynyldimethyldisiloxane; 1,3-divinyl-1,1,3,3-tetramethyldisiloxane, 1,3-divinyl-1,3-dimethyldisiloxane, di(acetato)dimethyl-silane, di(pivalato)dimethylsilane, 2,4,6,8-tetramethylcyclotetrasiloxane, 2,4,6,8-octamethylcyclotetrasiloxane.

Most organosilicon precursors of the present invention are available commercially through Gelest, Inc. and/or Hybrid Plastics Inc., both leading suppliers of silanes, or such precursors may be readily synthesized using methods that are well known in the art.

In one embodiment, (hereinafter referred to as Embodiment 6) the present invention relates to a chemical vapor deposition (CVD) process and more preferably a plasma enhanced chemical vapor deposition (PECVD) process for forming a low-k dielectric thin film on a substrate, including the steps of:

placing the substrate in a chemical vapor deposition apparatus,

introducing at least one vaporized organosilicon precursor comprising at least one cleavable organic functional group into the apparatus;

transporting the organosilicon vapor into a chemical vapor deposition zone containing a substrate, optionally using a carrier gas to effect such transport;

contacting the organosilicon vapor with the substrate under chemical vapor deposition conditions to deposit a thin film comprising an organosilicon composition; and

activating the organosilicon thin film to produce a porous SiOC, low-k dielectric thin film.

The activation step of Embodiment 6 is carried out under conditions sufficient to effect the removal of at least a portion of the cleavable, organic functional groups, optionally a portion of the alkyl groups (if present), and optionally to activate at least a portion of cross-linking functional groups (if present), to produce a porous, SiOC thin film having a dielectric constant of less than 3.0 and a hardness that is between 1.0 and 3.0 Gpa.

Useful sources of activation include but are not limited to chemical generation of free radicals, plasma, pulsed plasma, chemical quenching agents, co-reactants, initiators and combinations thereof.

In a further embodiment, (hereafter referred to as Embodiment 7) the present invention relates to a chemical vapor deposition (CVD) process and more preferably a plasma enhanced chemical vapor deposition (PECVD) process for forming a low-k dielectric thin film on a substrate, including the steps of:

placing the substrate in a chemical vapor deposition apparatus, introducing at least one vaporized organosilicon precursor comprising at least one cleavable organic functional group into the apparatus;

transporting the organosilicon vapor into a chemical vapor deposition zone containing a substrate, optionally using a carrier gas to effect such transport;

contacting the organosilicon vapor with the substrate under chemical vapor deposition conditions to deposit a thin film comprising an organosilicon composition; and

annealing the organosilicon thin film to produce a porous, SiOC, low-k dielectric thin film.

In a preferred embodiment the organosilicon thin film of Embodiments 6 and 7 retains between 1 and 100 percent of the cleavable, organic functional groups, more preferably the organosilicon thin film retains between about 25 to 100 percent of the cleavable organic functional groups and most preferably, the organosilicon thin film retains between about 50 to 100 percent of the cleavable organic functional groups.

In yet a further embodiment, (hereafter referred to as Embodiment 8) the present invention relates to a CVD process and more preferably a PECVD process, for forming low-k dielectric thin films on a substrate, including the steps of:

placing the substrate in a chemical vapor deposition apparatus;

introducing at least one vaporized organosilicon precursor comprising at least one cleavable organic functional group and at least one alkyl group into the apparatus;

transporting the organosilicon vapor into a chemical vapor deposition zone containing a substrate, optionally using a carrier gas to effect such transport;

contacting the organosilicon vapor with the substrate under chemical vapor deposition conditions to deposit a thin film comprising an organosilicon composition;

annealing the organosilicon thin film to produce a porous, SiOC, low-k dielectric thin film.

In a preferred embodiment the organosilicon thin film of Embodiment 7 retains between 1 to 100 percent of the cleavable, organic functional groups and between 1 to 100 percent of the alkyl groups; more preferably the organosilicon thin film retains between about 25 to 100 percent of the cleavable organic functional groups and between about 25 to 100 percent of the alkyl groups; and most preferably, the organosilicon thin film retains between about 50 to 100 percent of the cleavable organic functional groups and between about 50 to 100 percent of the alkyl groups.

The annealing step of Embodiments 7 and 8 is carried out at a temperature in the range of from about 100° C. to about 400° C., optionally in the presence of an inert carrier gas, an oxidizing gas and/or a reducing gas, for a length of time and under conditions sufficient to effect the removal of the cleavable, organic functional groups and optionally a portion of the alkyl groups (if present) to produce a porous, SiOC thin film having a dielectric constant of less than 3.0.

The annealing step of Embodiments 6 and 7 may further comprise plasma enhanced conditions, at a temperature in the range of from about 100 to about 400° C., optionally in the presence of an oxidizing or reducing gas, for a length of time and under conditions sufficient to effect the removal of the volatile organic groups and optionally a portion of the alkyl groups, to produce a porous, SiOC thin film having a dielectric constant of less than 3.0.

In a further embodiment (hereafter referred to as “Embodiment 9”) the present invention relates to an organosilicon precursor vapor comprising from about 1 to about 100% by volume of an organosilicon composition as described in Embodiments 1-4, and from about 0 to about 99% by volume of an inert carrier gas, based on the total volume of organosilicon precursor vapor and the inert carrier gas, is subjected to chemical vapor deposition (CVD) conditions, preferably plasma enhanced chemical vapor deposition conditions, in a chamber containing a substrate, so that the precursor composition in vapor or plasma form is contacted with the substrate in the CVD chamber to deposit thereon, a dense SiOC thin film comprising cleavable organic functional groups.

In a further embodiment (hereafter referred to as “Embodiment 10”) the present invention relates to an organosilicon precursor vapor comprising from about 1 to about 100% by volume of an organosilicon composition as described in Embodiments 34, and from about 0 to about 99% by volume of an inert carrier gas, based on the total volume of organosilicon precursor vapor and the inert carrier gas, is subjected to chemical vapor deposition (CVD) conditions, preferably plasma enhanced chemical vapor deposition conditions, in a chamber containing a substrate, so that the precursor composition in vapor or plasma form is contacted with the substrate in the CVD chamber to deposit thereon, a dense SiOC thin film comprising alkyl groups and cleavable organic functional groups.

In a further embodiment (hereafter referred to as “Embodiment 11”) an organosilicon precursor vapor comprising from about 1 to about 100% by volume of an organosilicon composition as described in Embodiments 1-4, from about 0 to about 99% by volume of an inert carrier gas, and from about 1 to about 99% by volume of at least one co-reactant, based on the total volume of organosilicon precursor vapor, inert carrier gas and co-reactant, is subjected to chemical vapor deposition (CVD) conditions, preferably plasma enhanced chemical vapor deposition conditions in a plasma chamber containing a substrate, so that the precursor composition in vapor or plasma form is contacted with the substrate in the CVD chamber to deposit thereon, a dense SiOC thin film comprising cleavable organic functional groups thereon.

In a still further embodiment (hereafter referred to as “Embodiment 11”) an organosilicon precursor vapor comprising from about 1 to about 100% by volume of an organosilicon composition as described in Embodiments 3-4, and from about 0 to about 99% by volume of an inert carrier gas and from about 1 to about 99% by volume of at least one co-reactant, based on the total volume of organosilicon precursor vapor, inert carrier gas and co-reactant, is subjected to chemical vapor deposition (CVD) conditions, preferably plasma enhanced chemical vapor deposition conditions in a plasma chamber containing a substrate, so that the precursor composition in vapor or plasma form is contacted with the substrate in the CVD chamber to deposit thereon, a dense SiOC thin film comprising alkyl groups and cleavable organic functional groups thereon.

For the purpose of depositing the organosilicon thin films of the present invention, the organosilicon compounds may optionally be used in combination with other co-reactants, i.e., other organosilicon precursors of the present invention, other organosilicon precursors, or reactive gases i.e. CO₂, ethylene, acetylene, N₂O, O₂, H₂ and mixtures thereof.

The inert carrier gas in the processes described hereinabove may be of any suitable type, i.e., argon, helium, nitrogen, etc. or a compressible gas or liquid, i.e., CO₂.

The processes of Embodiments 6, 7 and 8, may further include subjecting at least one organosilicon precursor as described hereinabove in Embodiments 1-4 to chemical vapor deposition (CVD) conditions in a CVD chamber containing a substrate, so that the precursor composition is deposited in such a form as to retain at least a portion of the original cleavable organic functional groups, and if present, at least a portion of the cross-linking functional groups, wherein the CVD conditions include temperature in the chamber in a range of from about 50° C. to about 400° C. and more preferably in a range of from about 250° C. to about 350° C., and a chamber pressure in a range of from about 500 mTorr to about 10 Torr , more preferably the chamber pressure is set to about 4 Torr.

Similarly, the processes of Embodiments 7, may further include subjecting at least one organosilicon precursor as described hereinabove in Embodiments 3 and 4 to chemical vapor deposition (CVD) conditions in a CVD chamber containing a substrate, so that the precursor composition is deposited in such a form as to retain a portion of the original alkyl and cleavable organic functional groups and if present, at least a portion of the cross-linking functional groups, wherein the CVD conditions include temperature in the chamber in a range of from about 50° C. to about 400° C. and more preferably in a range of from about 250° C. to about 350° C., and a chamber pressure in a range of from about 500 mTorr to about 10 Torr , more preferably the chamber pressure is set to about 4 Torr.

In the preferred PECVD process of Embodiments 6-11, the plasma may be generated from single or mixed frequency RF power. The plasma source may comprise a high frequency, radio frequency (HFRF) plasma source component generating power in a range of from about 75 W to about 200 W at a frequency of between 2 and 20 MHz, preferably about 13.56 MHz or a low frequency radio frequency (LFRF) plasma source component generating power in a range from about 5 W and 75 W at a frequency of about 350 kHz and/or combinations thereof. The plasma is maintained for a period of time sufficient to deposit the dense SiOC thin film having retained therein between 1 to 100 percent of the original alkyl groups and between 1 and 100 percent of the cleavable organic functional groups. In a preferred embodiment, the dense SiOC thin film retains between 50 to 100 percent of the original alkyl groups and between 50 to 100 percent of the original cleavable organic functional groups.

In a preferred embodiment, the deposition process of Embodiments 6-11 is tuned with single frequency or dual frequency operating simultaneously to yield a dense SiOC thin film wherein between 1 and 100 percent of the alkyl groups and between 1 and 100 percent of the cleavable organic functional groups are retained in the deposited film.

In a further embodiment, the dense SiOC film formed in Embodiment 6, 7 or 8 is post annealed in a furnace, at a temperature in the range of from about 100° C. to about 400° C., optionally in the presence of a carrier gas, an oxidizing a reducing gas, or combinations thereof, for a length of time and under conditions sufficient to effect the removal of at least a portion of the cleavable organic functional groups, a desired portion of the alkyl groups and if present to activate the cross-linking functional groups, to produce a porous, low dielectric constant, SiOC thin film.

The dense SiOC thin film may be optionally annealed at a gradually increasing temperature profile to effect the rearrangement and volatilization of the cleavable organic groups. In a preferred embodiment, the dense SiOC thin film is annealed at a temperature of about 400° C.

The post-annealing step as serves to activate the cleavable organic groups retained in the dense SiOC thin film in such a way as to effect the rearrangement and/or decomposition of the cleavable organic groups to form volatile organic liquid or gaseous by-products. A portion of the alkyl groups in the dense SiOC thin film retains the carbon, resulting in Si—C bonds. The final result is a micro-porous, low-k dielectric SiOC thin film.

In a preferred embodiment, the post-annealing step activates the cleavable functional groups by way of a rearrangement process that results in a volatile organic species and forms uniformly distributed pores throughout the thin film. The carbon concentration of the micro-porous, SiOC thin film may be tailored to give optimum carbon levels that result in a material with a lower dielectric constant and increased hardness, by varying process conditions that are well known to those skilled in the art.

In a further embodiment the post-annealing step occurs under plasma-enhanced or oxygen assisted plasma conditions.

To further promote the rearrangement process, the annealing step may further comprise: co-reactants, such as CO₂; oxidizing gases, such as O₂, O₃, N₂O, or NO; reducing gases such as H₂ or NH₃; inert gases, such as N₂, He or Ar; and/or combinations thereof.

In one embodiment the micro-porous, low dielectric constant, SiOC thin film of the instant invention comprises between 5 and 99 percent porosity, more preferably between 5 and 80 percent porosity and most preferably between 5 and 70 percent porosity.

The porosity of the micro-porous, SiOC thin film may be tailored to give optimum porosity levels that result is a material with a lower dielectric constant, by varying the percentage of cleavable organic functional groups in the organosilicon precursor(s) and by varying process conditions that are well known to those skilled in the art.

As used herein, the term porosity refers to that fraction of the low-k dielectric thin film that comprises air and includes molecular sized pores in the range of from about 5 to 20 nm, mesopores (between molecules) of less than 150 nm and micropores (within the particle), of less than 2 nm.

In a further embodiment, the micro-porous, low dielectric constant, SiOC thin film comprises between 1 and 20 percent carbon, more preferably between 1 and 15 percent carbon and most preferably between 1 and 10 percent carbon.

In a still further embodiment, the micro-porous, low dielectric constant, SiOC thin film of the instant invention has a measured hardness that is between 1.0 and 3.0 Gpa.

In a preferred embodiment the dielectric constant of the porous SiOC thin film produced by any one of the aforementioned embodiments is less than 3.0, more preferably the dielectric constant of the porous SiOC thin film is less than 2.0 and most preferably the dielectric constant of the porous SiOC thin film is less than 1.5.

Specific CVD conditions and more particularly PECVD conditions are readily determinable for a given application by empirically varying the process conditions (e.g., pressure, temperature, flow rate, relative proportions of the organosilicon precursor gas and inert carrier gas in the composition, etc.) and developing correlation to the film properties produced in the process. The conditions of the process as disclosed herein are monitored to retain alkyl and cleavable organic groups in the dense SiOC film.

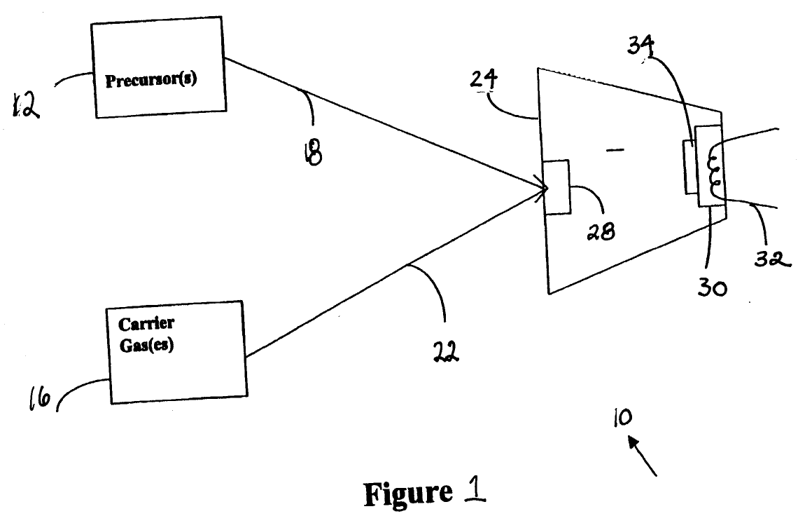

FIG. 1 is a schematic representation of a process system 10 for forming a low k dielectric film on a substrate in accordance with one embodiment of the invention.

In process system 10, a source 12 of organosilicon precursor(s) is joined by line 18 to disperser (i.e., showerhead or aerosol nozzle) 28 in CVD reactor 24. The CVD reactor may be constructed and arranged to carry out CVD involving thermal dissociation of the precursor vapor to deposit the desired SiOC film on the substrate 34 mounted on susceptor 30 heated by heating element 32. Alternatively, the CVD reactor may be constructed and arranged for carrying out plasma-enhanced CVD, by ionization of the precursor gas mixture.

A source 16 of carrier gases is also provided, joined by line 22 to the disperser 28 in CVD reactor 24.

The disperser 28 may comprise a showerhead nozzle, jet or the like which functions to receive and mix the feed streams from the respective sources 12, 14 and 16, to form a gaseous precursor mixture which then is flowed toward the substrate 34 on the heated susceptor 30. The substrate 34 may be a silicon wafer or other substrate element and material, on which the low k dielectric film is deposited.

In lieu of mixing the respective feed streams from lines 18 and 22 in the disperser, the streams may be combined in a mixing vessel or chamber upstream of the CVD reactor 24. Further, it will be appreciated that if the CVD reactor is configured and operated for carrying out PECVD, a plasma generator unit may be provided as part of or upstream of the CVD reactor 24.

The feed streams from sources 12 and 16 may be monitored in lines 18 and 22, respectively, by means of suitable monitoring devices (not shown in FIG. 1), and the flow rates of the respective streams may be independently controlled (by means such as mass flow controllers, pumps, blowers, flow control valves, regulators, restricted flow orifice elements, etc., also not shown) to provide a combined precursor feed stream having a desired compositional character.

The precursor formulations of the invention may be employed in any suitable chemical vapor deposition system to form corresponding thin films on a substrate or microelectronic device precursor structure as a dielectric layer thereon. The CVD system may for example comprise a liquid delivery CVD system, a bubbler-based CVD system, or a CVD system of any other suitable type. Suitable liquid delivery CVD systems include those disclosed in Kirlin et al. U.S. Pat. No. 5,204,134; Kirlin et al. U.S. Pat. No. 5,536,323; and Kirlin et al. U.S. Pat. No. 5,711,816.

In liquid delivery CVD, the source liquid may comprise the source reagent compound(s) or complex(es) per se, if the compound(s) or complex(es) are in the liquid phase at ambient temperature (e.g., room temperature, 25° C.) or otherwise at the supply temperature from which the source reagent is rapidly heated and vaporized to form precursor vapor for the CVD process. Alternatively, if the source reagent compound or complex is a solid at ambient or the supply temperature, such compound(s) or complex(es) can be dissolved or suspended in a compatible solvent medium to provide a liquid phase composition that can be submitted to rapid heating and vaporization to form precursor vapor for the CVD process. The precursor vapor resulting from the vaporization then is transported, optionally in combination with a carrier gas (e.g., He, Ar, H₂, O₂, etc.), to the chemical vapor deposition reactor where the vapor is contacted with a substrate at elevated temperature to deposit material from the vapor phase onto the substrate or semiconductor device precursor structure positioned in the CVD reactor.

In addition to flash vaporizer liquid delivery systems, other reagent delivery systems such as bubblers and heated vessels can be employed. In bubbler-based delivery systems, an inert carrier gas is bubbled through the precursor composition to provide a resulting fluid stream that is wholly or partially saturated with the vapor of the precursor composition, for flow to the CVD tool.

Accordingly, any method that delivers the precursor composition to the CVD tool may be usefully employed.

In a further embodiment, the present invention relates to a porous, dielectric, SiOC thin film produced by the process as described hereinabove in Embodiments 6 and 7. In a preferred embodiment the present invention relates to a porous dielectric thin film produced by the process as described hereinabove in Embodiments 6 and 7, wherein the dielectric constant of the thin film is less than 2. In a more preferred embodiment the present invention relates to a porous dielectric thin film produced by a process as described hereinabove in Embodiments 6 and 7, wherein the dielectric constant of the thin film is less than 1.5.

The following examples are provided to further exemplify the production and usefulness of compounds of the present invention. These examples are presented for illustrative purposes only, and are not in any way intended to limit the scope of the present invention

### EXAMPLES

Synthesis of Di(formato)dimethylsilane

Sodium formate (2 mols) is suspended in acetonitrile with continuous stirring at room temperature. Dimethyldichlorsilane (1 mol) dissolved in acetonitrile is slowly added to the sodium formate suspension in acetonitrile. The reaction mixture is allowed to stir after addition for an additional hour and refluxed for 30 mins. The reaction mixture is filtered and the solvent is removed under reduced pressure by distillation. The crude diformatodimethylsilane is purified by distillation.

PECVD of Di(formato)dimethylsilane

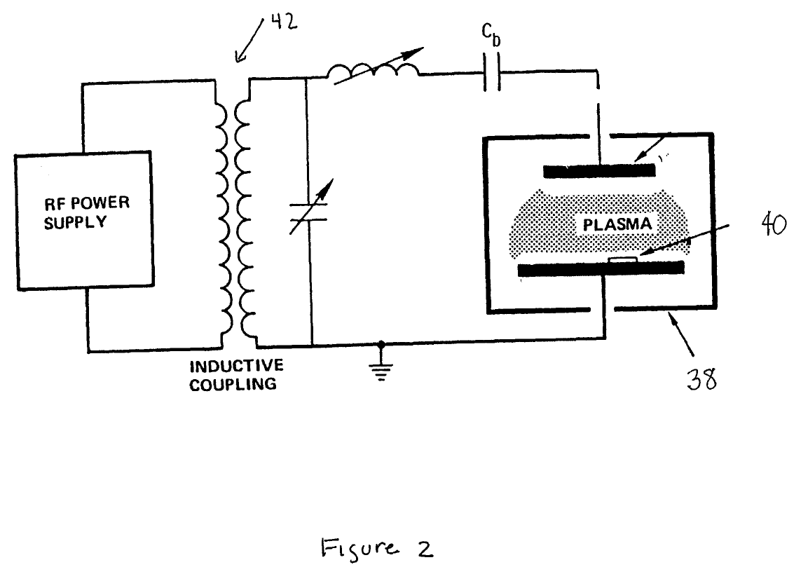

FIG. 2 is a schematic representation of a process system 10 for forming a low k dielectric film on a substrate in accordance with a preferred embodiment of the invention.

Di(formato)dimethylsilane is delivered into a PECVD deposition chamber 38 as a chemical vapor. Optionally, the di(formato)dimethylsilane may be delivered with a carrier gas. The chemical vapor is obtained either by vapor draw or by direct liquid injection of liquid into a vaporizer, which is heated to an elevated temperature.

In a first step, the deposition process is carried out on a substrate 40, typically a silicon wafer, at a temperature in a range of from about 100-400° C. in the presence of a single frequency or dual frequency (42) plasma activation. Film properties and deposition parameters are monitored as a function of plasma power, reactor pressure, oxygen to precursor ratio, and deposition temperature. The deposition process is monitored to obtain a film with the desired composition of SiₓO_{y}C_{z}. The process is optimized to retain the highest percentage of the functional groups and a desired percentage of the alkyl groups in the film.

In a second step, the process involves annealing at higher temperatures and or by additional plasma activation. In this step the functional groups are cleaved as volatile gaseous or high vapor pressure liquids that are removed continuously. Preferably, some of the methyl groups are retained in the deposited film. In the case of di(formato)dimethylsilane, the formato group is a cleavable functional group used to generate micro porosity in the resulting thin film. The volatile products generated by rearrangement and/or decomposition of the formato ligand include but are not limited CO, CO₂, and CH₂O

The cleavable formato ligand contains a □-hydrogen that under conditions as described herein, undergoes a rearrangement process that results in the formation of cleavable volatile products, i.e., CO, CO₂, and CH₂O, with high vapor pressure.

Similarly, other molecules containing alkyl and/or other functional groups with □-hydrogens may undergo rearrangements. Such rearrangement process results in formation of cleavable volatile products with high vapor pressures that undergo elimination reactions when subjected to conditions as described herein. Elimination of the organic groups results in micro-porosity that effectively reduces the dielectric constant of the SiOC thin film.

The above-described steps can be carried out either sequentially or separately in order to produce the porous, low-k dielectric thin films of the present invention.

Mass Spectroscopic Analysis of Di(formato)dimethylsilane

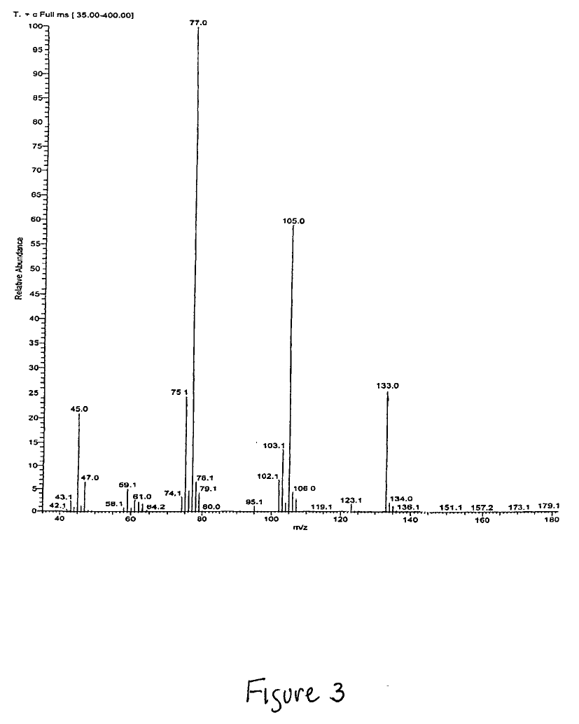

FIG. 3 shows a mass spectroscopic analysis of di(formato)dimethylsilane (CHOO)₂Si(CH₃)₂. The mass spectroscopic analysis evidences the fragmentation pattern of the molecule under mass spec conditions. A strong molecular ion peak at m/e 133 reveals loss of one CH₃ group with subsequent □-rearrangement of the formato hydrogens and loss of two CO groups as shown by molecular fragments at m/e 105 and m/e 77. The mass specification fragmentation pattern evidences the inherent tendency of the formato groups to rearrange and cleave as volatile by-products.

Although the invention has been variously disclosed herein with reference to illustrative aspects, embodiments and features, it will be appreciated that the aspects, embodiments and features described hereinabove are not intended to limit the invention, and that other variations, modifications and other embodiments will suggest themselves to those of ordinary skill in the art. The invention therefore is to be broadly construed, consistent with the claims hereafter set forth.

What is claimed is:

1. An organosilicon precursor useful for producing porous, low-k dielectric, SiOC thin films, wherein the organosilicon precursor is selected from the group consisting of:
I. 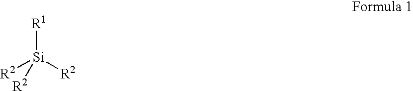
wherein
R¹ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinbelow, and ligand Y as described hereinbelow; and
each of R² is same or different and each of R² is selected from the group consisting of H, ligand X as described hereinbelow, ligand Y as described hereinbelow, C₂ to C₆ alkene, C₂ to C₆ alkyne, C₃ to C₄ allyl, C₁ to C₆ alkyl, C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane;
II. 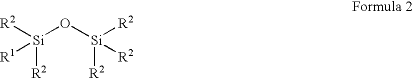
wherein
R¹ is a cleavable organic functional group, selected from the group consisting of C₂ to C₆ alkene, C₂ to C₆ alkyne, C₃ to C₄ allyl, C₁ to C₆alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinbelow, and ligand Y as described hereinbelow; and
each of R² is same or different and each of R² is selected from the group consisting of H, ligand X as described hereinbelow, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane; and
III. 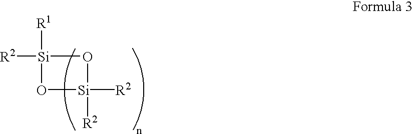
wherein
R¹ is a cleavable organic functional group, selected from the group consisting of C₂ to C₆ alkene, C₂ to C₆ alkyne, C₃ to C₄ allyl, C₁ to C₆ alkyl, C₃-C₆ fluoroalkyl, C₁ to C₆ perfluoroalkyl; C₃-C₆ cycloalkyl, C₆-C₁₀ aryl, C₆-C₁₀ fluoroaryl ligand X as described hereinbelow, and ligand Y as described hereinbelow; and
each of R² is same or different and each of R² is selected from the group consisting of H, ligand X as described hereinbelow, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane, and
n is an integer from 1 to 6.

2. The organosilicon precursor according to claim 1, wherein when said organosilicon precursor comprises the Formula 3 composition, at least one of R² may further comprise at least one cross-linking functional group selected from the group consisting of Si—H, Si—OH, alcohols, phenols, alkoxysilanes, epoxides, esters, methacrylates, styrenes, silanols, silanes, olefins, norborenes. Preferred cross-linking functional groups include Si—H and Si—OH.

3. The organosilicon precursor according to claim 1, wherein when said organosilicon precursor comprises the Formula 3 composition, at least one of R² may further comprise at least one cross-linking functional group selected from the group consisting of Si—H and Si—OH.

4. The organosilicon precursor according to claim 1 wherein the organosilicon precursor further comprises at least one alkyl group.

5. The organosilicon precursor according to claim 2, wherein the organosilicon precursor further comprises at least one alkyl group.

6. The organosilicon precursor according to claim 5, wherein the organosilicon precursor comprises a composition selected from the group consisting of:
IV. 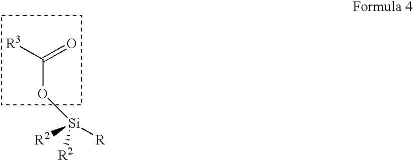
wherein
ligand X is a cleavable organic functional group as depicted in Formula 4;
R³ is selected from the group consisting of: H, C₁ to C₆ alkyl, C₁ to C₆ fluoroalkyl, C₁ to C₆ perfluoroalkyl, C₃ to C₆ cycloalkyl, C₃ to C₄ allyl, C₂ to C₆ alkene, C₆ to C₁₀aryl, C₆ to C₁₀ fluoroaryl, C₆ to C₁₀ perfluoroaryl, C₁ to C₆ carboxylate;
R is selected from the group consisting of: C₁ to C₄ alkyl, C₁ to C₄ fluoroalkyl and C₁ to C₄ perfluoroalkyl,
each of R² is same or different and each of R² is selected from the group consisting of H, ligand X as described hereinbelow, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane;
V. 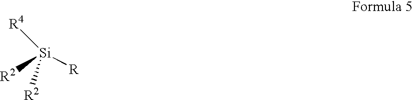
wherein
R⁴ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinabove, and ligand Y as described hereinbelow,
R is selected from the group consisting of: C₁ to C₄ alkyl, C₁ to C₄ fluoroalkyl and C₁ to C₄ perfluoroalkyl, and
each of R² is same or different and each of R² is selected from the group consisting of H, ligand X as described hereinabove, ligand Y as described hereinbelow, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane;
VI. 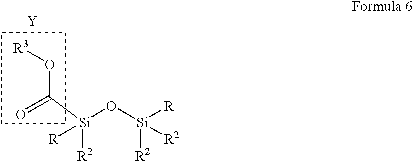
wherein
ligand Y is a cleavable organic functional group as depicted in Formula 6;
R³ is selected from the group consisting of: H, C₁ to C₆ alkyl, C₁ to C₆ fluoroalkyl, C₁ to C₆ perfluoroalkyl, C₃ to C₆ cycloalkyl, C₃ to C₄ allyl, C₂ to C₆ alkene, C₆ to C₁₀ aryl, C₆ to C₁₀ fluoroaryl, C₆ to C₁₀ perfluoroaryl, C₁ to C₆ carboxylate,
R is selected from the group consisting of: C₁ to C₄ alkyl, C₁ to C₄ fluoroalkyl and C₁ to C₄ perfluoroalkyl, and
each of R² is same or different and each of R² is selected from the group consisting of H, ligand X as described hereinabove, ligand Y as described hereinabove, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane;
VII. 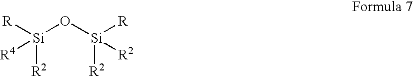
wherein
R⁴ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinabove, and ligand Y as described hereinabove,
R is selected from the group consisting of: C₁ to C₄ alkyl, C₁ to C₄ fluoroalkyl and C₁ to C₄ perfluoroalkyl, and
each of R² is same or different and each of R² is selected from the group consisting of H, ligand X as described hereinabove, ligand Y as described hereinabove, C₂ to C₆ alkene, C₂ to C₆ alkyne, C₃ to C₄ allyl, C₁ to C₆ alkyl, , C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane;
VIII. 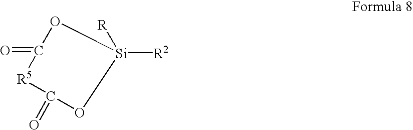
wherein
R⁵ is optional and may be selected from the group consisting of C₁ to C₂ alkyl,
R is selected from the group consisting of: C₁ to C₄ alkyl, C, to C₄ fluoroalkyl and C₁ to C₄ perfluoroalkyl, and each of R² is same or different and each of R² is selected from the group consisting of H, ligand X as described hereinabove, ligand Y as described hereinabove, C₂ to C₆ alkene, C₂ to C₆ alkyne, C₃ to C₄ allyl, C, to C₆ alkyl, C₁ to C₆ fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₆ to C₁₀ aryl, C₆ to C₁₀ fluoroaryl, C₆ to C₁₀ perfluoroaryl and C₂ to C₆ alkylsilane; and
IX. 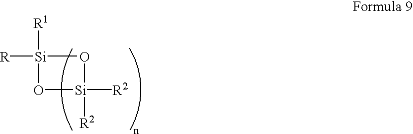
wherein
R¹ is a cleavable organic functional group, selected from the group consisting of C₂ to C₆ alkene, C₂ to C₆ alkyne, C₃ to C₄ allyl, C₁ to C₆ alkyl, C₁-C₆ fluoroalkyl, C₁ to C₆ perfluoroalkyl; C₃-C₆ cycloalkyl, C₆-C₁₀ aryl, C₆-C₁₀ fluoroaryl ligand X as described hereinabove, and ligand Y as described hereinabove;
R is selected from the group consisting of: C₁ to C₄ alkyl, C₁ to C₄ fluoroalkyl and C₁ to C₄ perfluoroalkyl, and
each of R² is same or different and each of R² is selected from the group consisting of H, ligand X as described hereinabove, ligand Y as described hereinabove, OH, C₂ to C₆ alkene, C₂ to C₆ alkyne, C₃ to C₄ allyl, C₁ to C₆ alkyl, , C₁ to C₆, fluoroalkyl, C₁ to C₆ perfluoroalkyl, C₃ to C₆ cycloalkyl, C₃ to C₆ fluorocycloalkyl C₃ to C₆ perfluorocycloalkyl, C₁ to C₆ alkoxy, C₁ to C₆ perfluoroalkoxy, C₆ to C₁₀ aryl, C₆ to C₁₀ fluoroaryl, C₆ to C₁₀ perfluoroaryl and C₂ to C₆ alkylsilane, C₂ to C₆ alkoxylsilane, C₂ to C₆ alkenesilane, C₂ to C₆ alkynesilane, and C₃ to C₄ allylsilane; and
n is an integer from 1 to 6.

7. The organosilicon precursor according to claim 6, wherein when said organosilicon precursor comprises the Formula 9 composition, at least one of R² may further comprise at least one cross-linking functional group selected from the group consisting of Si—H, Si—OH, alcohols, phenols, alkoxysilanes, epoxides, esters, methacrylates, styrenes, silanols, silanes, olefins, norborenes.

8. The organosilicon precursor according to claim 6, wherein when said organosilicon precursor comprises the Formula 9 composition, at least one of R² may further comprise at least one cross-linking functional group selected from the group consisting of Si—H, Si—OH.

9. The organosilicon precursor according to claim 1, wherein said organosilicon precursor is selected from the group consisting of: di(formato)methylsilane; di(formato)dimethylsilane; tri(formato)methylsilane; 1,3, dimethyl 1,1,3,3-tetra(formato)disiloxane; 1,3-di(formato)disiloxane; diethyldimethylsilane; triethylmethylsilane; di(t-butyl)methoxysilane, 1,3-Diethyl-1,3-dimethyldisiloxane; di-t-butylsilane; 1,3-di-t-butyl-1,1,3,3-tetramethyldisiloxane; di-isopropylsilane; 1,3-di-isopropyl-1,1,3,3-tetramethyldisiloxane; di-isobutylsilane; 1,3-di-isobuty-1-1,1,3,3,-tetramethyldisiloxane; t-butylsilane; 1,3-di-t-butyl-1,1,3,3-tetramethyldisiloxane; 1,3-diethyny-1,1,3,3-tetramethyldisiloxane; 1,3-diethynyldimethyldisiloxane; 1,3-divinyl-1,1,3,3-tetramethyldisiloxane, 1,3-divinyl-1,3-dimethyldisiloxane, di(acetato)dimethyl-silane, di(pivalato)dimethylsilane, 2,4,6,8-tetramethylcyclotetrasiloxane, 2,4,6,8-octamethylcyclotetrasiloxane

10. The organosilicon precursor according to claim 6, wherein said organosilicon precursor is selected from the group consisting of: di(formato)methylsilane; di(formato)dimethylsilane; tri(formato)methylsilane; 1,3, dimethyl 1,1,3,3- tetra(formato)disiloxane; 1,3-di(formato)disiloxane; diethyldimethylsilane; triethylmethylsilane; di(t-butyl)methoxysilane, 1,3-Diethyl-1,3-dimethyldisiloxane; di-t-butylsilane; 1,3-di-t-butyl-1,1,3,3- tetramethyldisiloxane; di-isopropylsilane; 1,3-di-isopropyl-1,1,3,3- tetramethyldisiloxane; di-isobutylsilane; 1,3-di-isobuty-1-1,1,3,3,- tetramethyldisiloxane; t-butylsilane; 1,3-di-t-butyl-1,1,3,3-tetramethyldisiloxane; 1,3-diethyny-1,1,3,3-tetramethyldisiloxane; 1,3-diethynyldimethyldisiloxane; 1,3-divinyl-1,1,3,3-tetramethyldisiloxane, 1,3-divinyl-1,3-dimethyldisiloxane, di(acetato)dimethyl-silane, di(pivalato)dimethylsilane, 2,4,6,8-tetramethylcyclotetrasiloxane, 2,4,6,8-octamethylcyclotetrasiloxane

11. A CVD process for producing a porous, low dielectric constant, SiOC thin film on a substrate, from at least one organosilicon precursor comprising at least one cleavable, organic functional group that upon activation, rearranges, decomposes and cleaves as a highly volatile liquid or gaseous by-product, wherein said organosilicon precursor comprises a composition selected from Formulas 1-9.

12. The CVD process according to claim 11, wherein the CVD process comprises:
placing the substrate in a chemical vapor deposition apparatus;
introducing at least one vaporized organosilicon precursor comprising at least one cleavable organic functional group into the apparatus;
transporting the organosilicon vapor into a chemical vapor deposition zone containing a substrate, optionally using a carrier gas to effect such transport;
contacting the organosilicon vapor with the substrate under chemical vapor deposition conditions to deposit a thin film comprising an organosilicon composition;
activating the organosilicon thin film to produce a porous SiOC, low-k dielectric thin film.

13. The CVD process according to claim 12, wherein said activation step is selected from the group consisting of, chemical generation of free radicals, plasma, pulsed plasma, chemical quenching agents, co-reactants, initiators and combinations thereof.

14. The CVD process according to claim 12, wherein said activation step includes annealing the organosilicon thin film.

15. The CVD process according to claim 12, wherein porous SiOC thin film has a hardness that is between 1.0 and 3.0 Gpa.

16. The CVD process according to claim 12, wherein the porous SiOC thin film comprises between about 1 and 20 percent carbon.

17. The CVD process according to claim 12 wherein the CVD process is PECVD.

18. The CVD process according to claim 12, wherein the organosilicon precursor is selected from the group consisting of, di(formato)methylsilane; di(formato)dimethylsilane; tri(formato)methylsilane; 1,3, dimethyl 1,1,3,3- tetra(formato)disiloxane; 1,3-di(formato)disiloxane; diethyldimethylsilane; triethylmethylsilane; di(t-butyl)methoxysilane, 1,3-Diethyl-1,3-dimethyldisiloxane; di-t-butylsilane; 1,3-di-t-butyl-1,1,3,3- tetramethyldisiloxane; di-isopropylsilane; 1,3-di-isopropyl-1,1,3,3- tetramethyldisiloxane; di-isobutylsilane; 1,3-di-isobuty-1-1,1,3,3,- tetramethyldisiloxane; t-butylsilane; 1,3-di-t-butyl-1,1,3,3- tetramethyldisiloxane; 1,3-diethyny-1,1,3,3-tetramethyldisiloxane; 1,3-diethynyldimethyldisiloxane; 1,3-divinyl-1,1,3,3-tetramethyldisiloxane, 1,3-divinyl-1,3-dimethyldisiloxane, di(acetato)dimethyl-silane, di(pivalato)dimethylsilane, 2,4,6,8-tetramethylcyclotetrasiloxane, 2,4,6,8-octamethylcyclotetrasiloxane

19. The CVD process according to claim 12, wherein the CVD process comprises more than one organosilicon precursor.

20. The CVD process according to claim 12, wherein the CVD process further comprises a process gas.

21. The CVD process according to claim 20, wherein the process gas is selected from the group consisting of: CO₂, ethylene, acetylene, N₂O, O₂, H₂ and mixtures thereof.

22. The CVD process according to claim 12, wherein the organosilicon vapor comprises between 1 and 100 percent by volume of an organosilicon precursor vapor and between 1 to about 100 percent by volume of an inert carrier gas, based on the total volume of organosilicon precursor vapor and the inert carrier gas.

23. The CVD process according to claim 12, wherein the inert carrier gas is selected from the group consisting of nitrogen, argon and helium.

24. The CVD process according to claim 12, wherein the organosilicon vapor comprises between 1 and 100 percent by volume of an organosilicon precursor vapor, between 1 and 100 percent by volume of an inert carrier gas, and about 1 to 100 percent by volume of a co-reactant, based on the total volume of organosilicon precursor vapor, the inert carrier gas and the co-reactant.

25. The CVD process according to claim 24, wherein the co-reactant is selected from the group consisting of: CO₂, ethylene, acetylene, N₂O, O₂, H₂ and mixtures thereof.

26. The CVD process according to claim 12, wherein the organosilicon composition retains between 50 to 95 percent of the original cleavable organic functional groups.

27. The CVD process according to claim 12, wherein the CVD conditions include a chamber temperature in the chamber in a range of from about 50° C. to about 400° C.

28. The CVD process according to claim 12, wherein the CVD conditions include a chamber temperature in a range of between 250° C. to about 350° C.

29. The CVD process according to claim 12, wherein the CVD conditions include a chamber pressure in a range of from about 500 mTorr to about 10 Torr.

30. The CVD process according to claim 12, wherein the CVD conditions include a chamber pressure of about 4 Torr.

31. The CVD process according to claim 12, wherein the CVD conditions include a single or mixed frequency RF power source.

32. The CVD process according to claim 12, wherein the annealing step further comprises an oxidizing or reducing gas.

33. The CVD process according to claim 12, wherein the annealing step occurs under plasma-enhanced or oxygen assisted plasma conditions.

34. The CVD process according to claim 12, wherein the organosilicon thin film is annealed at a gradually increasing temperature profile to a temperature between 100° C. and 400° C.

35. The CVD process according to claim 12, wherein the organosilicon thin film is annealed at a temperature of 400° C.

36. The CVD process according to claim 12, wherein the annealing step further comprises CO₂.

37. The CVD process according to claim 12, wherein the annealing step further comprises an oxidizing gas, a reducing gas or combinations thereof.

38. The CVD process according to claim 12, wherein the annealing step further comprises an oxidizing gas selected from the group consisting of: O₂, O₃, N₂O, NO and combinations thereof.

39. The CVD process according to claim 13, wherein the annealing step further comprises a reducing gas selected from the group consisting of H₂ or NH₃.

40. The CVD process according to claim 12, wherein the annealing step further comprises an inert gas selected from the group consisting of: He, Ar and combinations thereof.

41. The CVD process according to claim 12, wherein the microporous, low-k dielectric, SiOC thin film comprises between 5 and 99 percent porosity.

42. The CVD process according to claim 12, wherein the microporous, low-k dielectric, SiOC thin film comprises between 5 and 80 percent porosity.

43. The CVD process according to claim 12, wherein the microporous, low-k dielectric, SiOC thin film comprises between 5 and 70 percent porosity.

44. The CVD process according to claim 12, wherein the microporous, low-k dielectric, SiOC thin film comprises between 1 and 20 atomic percent carbon.

45. The CVD process according to claim 12, wherein the microporous, low-k dielectric, SiOC thin film comprises between 1 and 15 atomic percent carbon.

46. The CVD process according to claim 12, wherein the microporous, low-k dielectric, SiOC thin film comprises between 1 and 10 percent carbon.

47. The CVD process according to claim 12, wherein the microporous, low-k dielectric, SiOC thin film comprises a dielectric constant of less than 3.0.

48. The CVD process according to claim 12, wherein the microporous, low-k dielectric, SiOC thin film comprises a dielectric constant of less than 2.0.

49. The CVD process according to claim 12, wherein the microporous, low-k dielectric, SiOC thin film comprises a dielectric constant of less than 1.5.

50. A porous, low-k dielectric thin film made by the process of claim 12.

51. The porous, low-k dielectric thin film according to claim 50, having a hardness that is between 1.0 and 3.0 Gpa.
